(19) United States
(12) Patent Application Publication
(10) Pub. No.: US 2026/0213127 A1
(43) Pub. Date: Jul. 23, 2026

(54) EVALUATION PATTERN FORMATION METHOD AND POSITION VARIATION EVALUATION METHOD

(71) Applicant: NuFlare Technology, Inc., Yokohama-shi (JP)

(72) Inventors: Shunsuke ISAJI, Kouza-gun (JP); Satoru HIROSE, Yokohama-shi (JP)

(73) Assignee: NuFlare Technology, Inc., Yokohama-shi (JP)

(21) Appl. No.: 19/454,516

(22) Filed: Jan. 21, 2026

(30) Foreign Application Priority Data
Jan. 22, 2025 (JP) 2025-009298

(51) Int. Cl. H01J 37/304; H01J 37/317; H10P 72/50

(52) U.S. Cl. CPC H01J 37/3045; H01J 37/3174; H01J 2237/24578; H10P 72/53

(57) ABSTRACT

In one embodiment, an evaluation pattern formation method includes a step of irradiating a charged particle beam onto a sample to write a plurality of first patterns having different pattern densities, and a step of writing a plurality of second patterns having different pattern densities so that, when combined with at least some of the plurality of first patterns, each pattern achieves the same pattern density, thereby forming a plurality of evaluation patterns with the same pattern density.

### CROSS REFERENCE TO RELATED APPLICATION

This application is based upon and claims benefit of priority from the Japanese Patent Application No. 2025-9298, filed on Jan. 22, 2025, the entire contents of which are incorporated herein by reference.

### FIELD

The present invention relates to an evaluation pattern formation method and a position variation evaluation method.

### BACKGROUND

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed. The highly precise original image pattern is written by using an electron beam writing apparatus, in which a technology commonly known as electron beam lithography is used.

As an electron beam writing apparatus, for example, a multi-beam writing apparatus is known in which many beams are irradiated simultaneously using multiple beams to improve throughput. In this multi-beam writing apparatus, for example, an electron beam emitted from an electron source is passed through an aperture member having multiple openings to form multiple beams. Each beam is subjected to blanking control, and the beams that are not blanked are reduced by an optical system and written onto a substrate placed on a movable stage.

A multi-beam writing apparatus irradiates multiple beams simultaneously and writes a desired pattern shape by connecting beams formed through the same or different openings of the aperture member. Accordingly, the shape of the overall beam array image irradiated onto the substrate (hereinafter also referred to as the “beam array shape”) affects the stitching accuracy of written pattern.

It is known that the beam array shape varies (rotates, enlarges/reduces) depending on the amount of irradiation. Because the irradiation amount depends on a pattern density, the extent of the effect of the pattern density on the beam array shape (the irradiation positions of a plurality of individual beams in a multi-beam) is measured in advance, and a correction amount for the irradiation amount and the irradiation position at the time of product pattern writing is determined.

Conventionally, as illustrated in FIG. 9, an evaluation pattern is written which includes, for example, cross-shaped position measurement patterns 81 arranged at regular intervals, and a plurality of density adjustment patterns 82 having different densities, each arranged between the position measurement patterns 81, and after etching and developing processes, the positions of the position measurement patterns are measured, and the effect of the pattern density on the beam irradiation position is examined.

However, in such a conventional evaluation pattern, the position measurement patterns 81 and the density adjustment patterns 82 are provided separately, and the pattern density of each position measurement pattern 81 itself cannot be changed. Therefore, it is difficult to accurately estimate the effect of the pattern density on the beam irradiation position.

The density adjustment patterns 82 around each position measurement pattern 81 have different pattern densities. A measuring instrument to measure the position of the position measurement pattern 81 uses light, and when the state around the position measurement pattern varies, the effect on reflection of light also changes, and a problem arises in that the position measurement accuracy may deteriorate.

The tension of a light shielding film on the substrate changes according to the pattern densities of the density adjustment patterns 82. Therefore, during the etching and developing processes, a positional deviation of the patterns may occur due to this change.

Thus, in the conventional evaluation pattern, it is difficult to accurately measure the effect of the pattern densities on the beam irradiation position.

### BRIEF DESCRIPTION OF THE DRAWINGS

FIG. 1 is a schematic diagram of a writing apparatus according to an embodiment of the present invention.

FIG. 2 is a schematic diagram of an aperture member.

FIG. 3 is a conceptual diagram for explaining an example of a writing operation.

FIGS. 4A to 4C are diagrams for explaining a method of measuring a pattern density-dependent beam irradiation position variation.

FIG. 5 is a diagram for explaining an evaluation pattern writing method.

FIG. 6 is a diagram for explaining an evaluation pattern writing method.

FIG. 7 is a diagram for explaining an evaluation pattern writing method.

FIG. 8 is a diagram illustrating a method for writing and measuring an evaluation pattern.

FIG. 9 is a diagram illustrating a method for writing an evaluation pattern according to a comparative example.

### DETAILED DESCRIPTION

In one embodiment, an evaluation pattern formation method includes a step of irradiating a charged particle beam onto a sample to write a plurality of first patterns having different pattern densities, and a step of writing a plurality of second patterns having different pattern densities so that, when combined with at least some of the plurality of first patterns, each pattern achieves the same pattern density, thereby forming a plurality of evaluation patterns with the same pattern density.

Hereinafter, in the embodiments, a configuration using an electron beam as an example of a charged particle beam will be described. However, the charged particle beam is not limited to an electron beam, and a beam using charged particles such as an ion beam may also be employed.

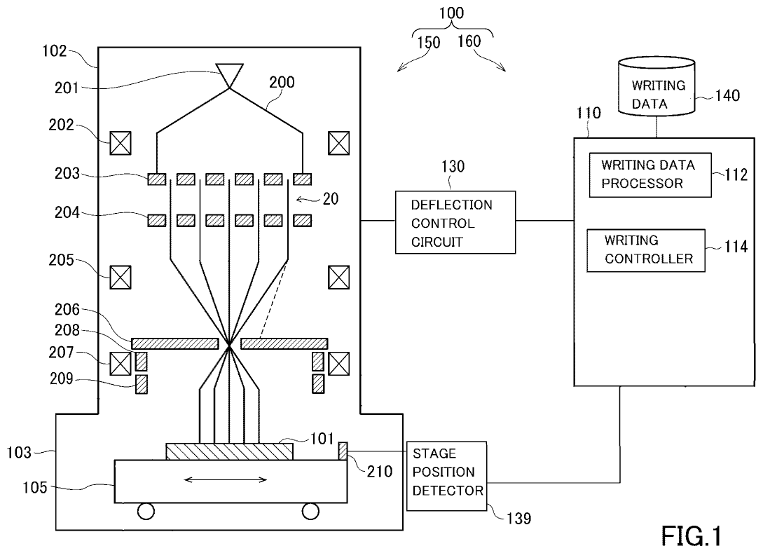

FIG. 1 is a conceptual diagram illustrating the configuration of a writing apparatus according to an embodiment. In FIG. 1, a writing apparatus 100 includes a writing unit 150 and a controller 160. The writing apparatus 100 is an example of a multi-charged particle beam writing apparatus. The writing unit 150 includes an electron column 102 and a writing chamber 103.

In the electron column 102, an electron source 201, an illumination lens 202, a shaping aperture array substrate 203, a blanking aperture array substrate 204, a reduction lens 205, a limiting aperture member 206, an objective lens 207, and deflectors 208 and 209 are disposed.

An XY stage 105 is disposed in the writing chamber 103. A sample 101, such as a mask, which serves as a writing target substrate, is placed on the XY stage 105. The sample 101 is, for example, an exposure mask when a semiconductor device is fabricated, a semiconductor substrate (silicon wafer) and a mask blank in which a semiconductor device is fabricated. On the XY stage 105, a mirror 210 for measuring the position of the XY stage 105 is further disposed.

The controller 160 includes a control computer 110, a deflection control circuit 130, a stage position detector 139 and a storage device 140 such as a magnetic disk drive. The storage device 140 (storage unit) stores writing data.

In the control computer 110, a writing data processor 112 and a writing controller 114 are disposed. The function of the writing data processor 112 and the writing controller 114 may be implemented by hardware such as an electric circuit, or implemented by software such as a program that executes these functions. Alternatively, the function may be implemented by a combination of hardware and software. Information input to and output from the writing data processor 112 and the writing controller 114, as well as information during calculation, is stored in a memory (not illustrated) as required.

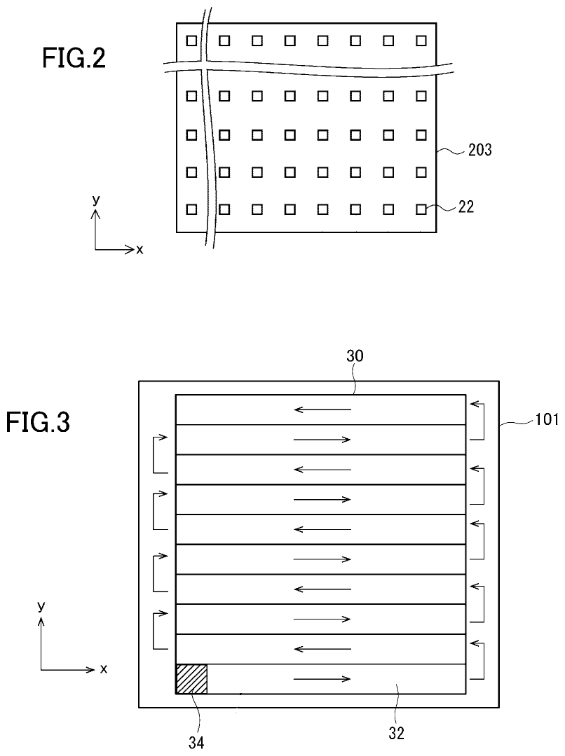

FIG. 2 is a conceptual view showing the configuration of the shaping aperture array substrate 203. In the shaping aperture array substrate 203, openings 22 in m vertical (y direction) rows×n horizontal (x direction) rows (m, n≥2) are formed in a matrix with a predetermined arrangement pitch. For example, 512×512 openings 22 are formed vertically and horizontally (x, y directions). The openings 22 are formed, for example, in rectangular or circular shapes with the same dimensions. A multi-beam 20 is formed by passing part of the electron beam 200 through a corresponding one of the plurality of openings 22.

In the blanking aperture array substrate 204, passage holes (openings) for passing individual beams of the multi-beam are opened at the positions corresponding to the openings 22 of the shaping aperture array substrate 203 illustrated in FIG. 2. In the vicinity of each passage hole, a set (a blanker, i.e., a blanking deflector) of two electrodes for blanking deflection is disposed across the passage hole.

FIG. 3 is a conceptual view for explaining an example of a writing operation. As illustrated in FIG. 3, a writing region 30 of the sample 101 is virtually divided into e.g., a plurality of long rectangular stripe regions 32 with a predetermined width in y direction. Each stripe region 32 is a writing unit region. First, the XY stage 105 is moved, and an irradiation region 34 which can be irradiated with the multi-beam 20 at one time is adjusted to be located at the left end or a further left position of the first stripe region 32, then writing is started.

When writing is performed on the first stripe region 32, writing proceeds relatively in +x direction, for example, by moving the XY stage 105 in −x direction. The XY stage 105 is continuously moved at a predetermined speed. After writing on the first stripe region 32 is completed, the stage position is moved in −y direction, and the irradiation region 34 is adjusted to be located relatively in +y direction at the right end or a further right position of the second stripe region 32. This time, the XY stage 105 is moved, for example, in +x direction, thus writing is similarly performed in −x direction.

In the third stripe region 32, writing is performed in +x direction, and in the fourth stripe region 32, writing is performed in −x direction. The writing time can be reduced while alternately changing the direction in this manner. However, writing is not necessarily performed while alternately changing the direction, and when writing is performed on each stripe region 32, writing may be performed in the same direction. In one shot, a plurality of shot patterns at most equal in number to the openings 22 are formed at one time by the multi-beam which is formed by passing the beam through the openings 22 of the shaping aperture array substrate 203.

The writing data processor 112 reads writing data from the storage device 140, and performs a multi-stage data conversion process to generate shot data. The shot data defines, for each irradiation region, whether irradiation is to be performed and the irradiation time. Each irradiation region is obtained by dividing the writing surface of the sample 101 into a plurality of grid-like regions, for example, according to the beam size.

Tracking control by beam deflection is started so that the writing positions of the individual beams of the multi-beam 20 collectively follow the movement of the XY stage 105. Specifically, the stage position detector 139 irradiates the mirror 210 with a laser, and receives light reflected from the mirror 210, thereby measuring the position of the XY stage 105. The measured position of the XY stage 105 is output to the control computer 110. The writing controller 114 outputs a control signal to the deflection control circuit 130 based on the shot data and stage position information.

In the deflection control circuit 130, deflection amount data (tracking deflection data) is calculated to cause the beam to follow the movement of the XY stage 105. The tracking deflection data, which is a digital signal, is converted to an analog signal and applied to the deflector 208 as a tracking deflection voltage.

The writing unit 150 emits corresponding ON beams of the multi-beam 20 to the writing positions of the beams for corresponding writing times within a preset maximum writing time while performing tracking control. Specifically, the writing unit 150 operates as follows.

The electron beam 200 emitted from the electron source 201 (emitter) illuminates the entire shaping aperture array substrate 203 substantially perpendicularly by the illumination lens 202. Part of the electron beam 200 passes through the plurality of openings 22 provided in the shaping aperture array substrate 203, thereby forming a plurality of electron beams (multi-beam) 20 e.g., in a rectangular shape. The multi-beam 20 passes through corresponding blankers of the blanking aperture array substrate 204. The blankers deflect (perform blanking deflection on) each beam of the individually passing multi-beam 20 so that the beam is set beam-ON only for a calculated writing time (irradiation time), and is set beam-OFF for non-writing time.

The multi-beam 20 which has passed through the blanking aperture array substrate 204 is reduced by the reduction lens 205, and travels to the central opening formed in the limiting aperture member 206. An individual beam deflected to be beam-OFF by a blanker of the blanking aperture array substrate 204 is displaced from the central opening of the limiting aperture member 206 (blanking aperture member) and blocked by the limiting aperture member 206. In contrast, an individual beam not deflected by any blanker of the blanking aperture array substrate 204 passes through the central opening of the limiting aperture member 206. Blanking control is performed by ON/OFF of an individual blanking mechanism, and ON/OFF is controlled for each individual beam.

In this manner, the limiting aperture member 206 blocks the individual beam deflected to be in a beam-OFF state by the individual blanking mechanism. The beam for one shot is formed by the beam which has passed through the limiting aperture member 206 since beam-ON until beam-OFF is achieved.

The multi-beam 20 which has passed through the limiting aperture member 206 is focused by the objective lens 207 to form a pattern image with a desired reduction ratio. The beams are then collectively deflected in the same direction by the deflector 209 and irradiated onto respective writing positions (irradiation positions) on the sample 101.

The beams of the multi-beam 20 irradiated at one time are ideally arranged with the pitch which is the product of the arrangement pitch of the plurality of openings of the shaping aperture array substrate 203 and the above-mentioned desired reduction ratio. The writing apparatus 100 emits a large number of individual beams at one time, and writes a pattern of a desired figure shape by connecting the individual beams to fill the beam pitch. Thus, the beam array shape has a significant effect on the writing accuracy. The beam array shape (the irradiation positions of the plurality of individual beams) varies depending on the irradiation amount. The irradiation amount varies with the pattern density, thus it is necessary to measure the effect of the pattern density on the beam irradiation position, and correct the beam irradiation position and the irradiation amount of each individual beam.

A method of measuring a pattern density-dependent beam irradiation position variation will be described.

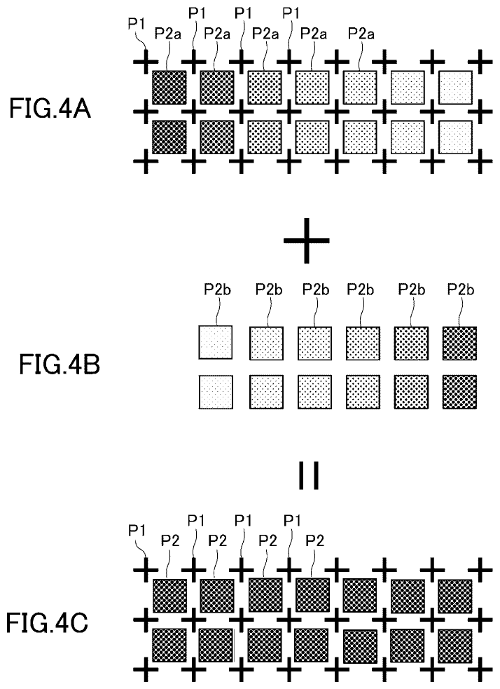

First, on the sample 101, a plurality of position measurement patterns P1 and first density adjustment patterns P2a as illustrated in FIG. 4A are written.

For example, each position measurement pattern P1 has a cross shape.

Each first density adjustment pattern P2a is arranged in the area between the position measurement patterns P1. For example, each first density adjustment pattern P2a is arranged in a rectangular area surrounded by four position measurement patterns P1. The pattern shape of the first density adjustment pattern P2a is not particularly limited, and may be, for example, a line-and-space pattern or a contact hole pattern. The first density adjustment pattern P2a has a pattern density varying from area to area. For example, an area located more rightward in FIG. 4A has a lower pattern density.

After writing the position measurement patterns P1 and the first density adjustment patterns P2a on the entire surface or a predetermined area of the writing region on the sample 101, second density adjustment patterns P2b as illustrated in FIG. 4B are written. The second density adjustment patterns P2b are arranged so as to overlap the arrangement regions of the first density adjustment patterns P2a.

The second density adjustment patterns P2b each have a pattern density varying from area to area, and differ from the first density adjustment patterns P2a in that the pattern density changes in an opposite manner. For example, the pattern density becomes higher toward the right side of FIG. 4B.

Overlapping the first density adjustment patterns P2a with the second density adjustment patterns P2b forms patterns P2 with the same pattern density in respective areas as illustrated in FIG. 4C.

After writing an evaluation pattern formed by the position measurement patterns P1, the first density adjustment patterns P2a and the second density adjustment patterns P2b, developing and etching are performed, and the positions of the position measurement patterns P1 are measured by a position measuring instrument (not illustrated).

The position measurement patterns P1 are written with the first density adjustment patterns P2a, thus are written at positions each of which is affected by a pattern density. In contrast, at the time of position measurement, all the patterns P2 have the same pattern density, and the states around the position measurement patterns P1 are the same. Since the patterns P2 have the same effect on reflection of the light used for position measurement, the position of each position measurement pattern P1 can be accurately measured.

In this manner, according to the present embodiment, the pattern density-dependent beam irradiation position variation can be accurately measured.

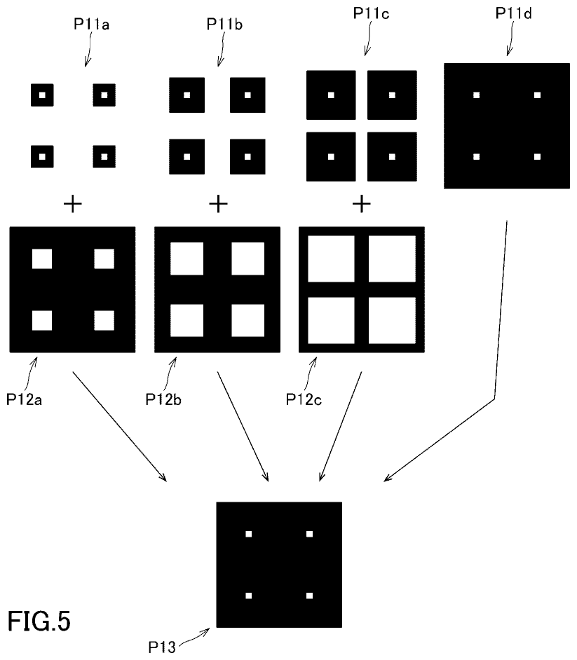

An evaluation pattern writing method for measuring a pattern density-dependent beam irradiation position variation according to another embodiment will be described using FIG. 5.

First, on the sample 101, a plurality of position measurement patterns P11a to P11d are written. The position measurement patterns P11a to P11d are dot patterns which have different pattern densities. In the example illustrated in FIG. 5, the pattern densities are such that P11a<P11b<P11c<P11d.

After writing the position measurement patterns P11a to P11d, density adjustment patterns P12a to P12c are written. The density adjustment patterns P12a to P12c are each a grid-like pattern, and arranged to surround the position measurement patterns P11a to P11c, respectively.

The density adjustment patterns P12a to P12c have different pattern densities. In the example illustrated in FIG. 5, the pattern densities are such that P12a>P12b>P12c.

A dot pattern P13 is obtained by combining the position measurement pattern P11a and the density adjustment pattern P12a. The dot pattern P13 with the same pattern density is also obtained by combining the position measurement pattern P11b and the density adjustment pattern P12b. In addition, the dot pattern P13 with the same pattern density is also obtained by combining the position measurement pattern P11c and the density adjustment pattern P12c.

In this example, the position measurement pattern P11d has the same pattern density as that of the dot pattern P13, thus does not need to be combined with a density adjustment pattern.

After writing a plurality of dot patterns P13 (evaluation pattern) formed by the position measurement patterns P11a to P11d and the density adjustment patterns P12a to P12c, the developing and etching process is performed, and the positions of the dots (pattern edges) of the dot patterns P13 are measured by a position measuring instrument (not illustrated).

The position measurement patterns P11a to P11d have different pattern densities, and are written at positions each of which is affected by a pattern density. In contrast, at the time of position measurement of dots, the pattern edges of the dot pattern P13 are P11a to P11d, thus a result of positions affected by the pattern densities of P12a to P12c is not observed, but a result of positions affected by the pattern densities of P11a to P11d is measured. All the dot patterns P13 have the same pattern density, and the states around the dots are the same. Thus, the pattern density-dependent beam irradiation position variation can be accurately measured.

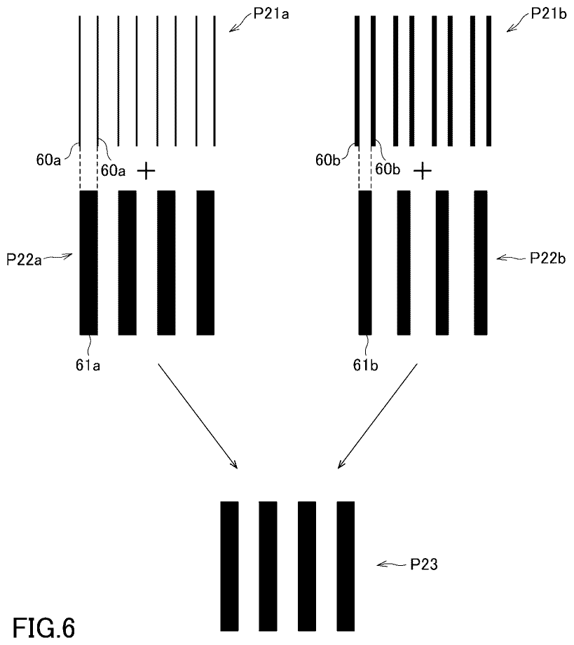

An evaluation pattern writing method for measuring a pattern density-dependent beam irradiation position variation according to another embodiment will be described using FIG. 6.

First, on the sample 101, position measurement patterns P21a, P21b are written. The position measurement patterns P21a, P21b are line and space patterns with different line widths. The pattern density can be changed in any way by controlling the line width of each line and space pattern. The position measurement patterns P21a, P21b have different pattern densities.

After writing the position measurement patterns P21a, P21b, density adjustment patterns P22a, P22b are written. The density adjustment patterns P22a, P22b, are line and space patterns, and line portions 61a, 61b are arranged between two line portions 60a, 60b of the position measurement patterns P21a, P21b, respectively.

Specifically, one line portion 61a of the density adjustment pattern P22a is arranged between two line portions 60a of the position measurement pattern P21a, thus one line portion is formed. The interval between the two line portions 60a is equal to the line width of the line portion 61a.

Similarly, one line portion 61b of the density adjustment pattern P22b is arranged between two line portions 60b of the position measurement pattern P21b, thus one line portion is formed. The interval between the two line portions 60b is equal to the line width of the line portion 61b.

Line and space pattern P23 is obtained by combining the position measurement pattern P21a and the density adjustment pattern P22a. The line and space pattern P23 with the same pattern density is obtained by combining the position measurement pattern P21b and the density adjustment pattern P22b. For example, a line and space pattern with a pattern density of 50% is written by combining the position measurement pattern P21a and the density adjustment pattern P22a, and a line-and-space pattern with a pattern density of 50% is written by combining the position measurement pattern P21b and the density adjustment pattern P22b.

After writing a plurality of line and space patterns P23 (evaluation pattern) formed by the position measurement patterns P21a, P21b and the density adjustment patterns P22a, P22b, the developing and etching processes are performed, and the positions of the pattern edges of the formed line and space patterns P23 are measured by a position measuring instrument (not illustrated).

The position measurement patterns P21a, P21b have different pattern densities, and are written at positions each of which is affected by a pattern density. In contrast, at the time of position measurement of pattern edges, the pattern edges of line-and-space patterns P23 are P21a, P21b, thus a result of positions affected by the pattern densities of P22a, P22b is not observed, but a result of positions affected by the pattern densities of P21a, P21b is measured. All the line-and-space patterns P23 have the same pattern density, and the surrounding states are the same. Thus, the pattern density-dependent beam irradiation position variation can be accurately measured.

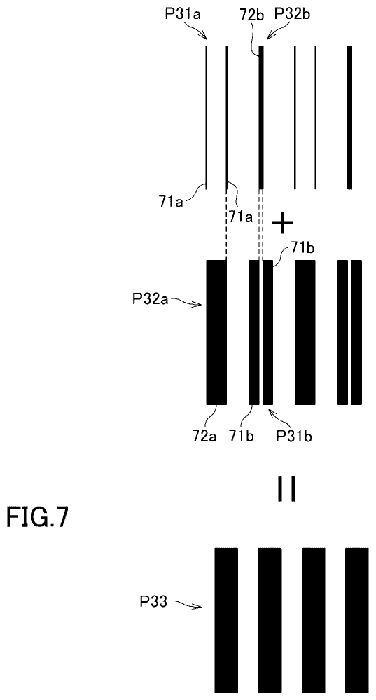

In the example illustrated in FIG. 6, a situation has been described in which the position measurement patterns P21a, P21b with a pattern edge as a measurement target are written in the first pass, and density adjustment patterns are written in the second pass; however, position measurement patterns and density adjustment patterns may be written in each of the first pass and the second pass. This evaluation pattern writing method will be described using FIG. 7.

First, on the sample 101, position measurement pattern P31a and density adjustment pattern P32b are written. The position measurement pattern P31a and the density adjustment pattern P32b are line-and-space patterns.

After writing the position measurement pattern P31a and the density adjustment pattern P32b, density adjustment pattern P32a and position measurement pattern P31b are written. The density adjustment pattern P32a and the position measurement pattern P31b are a line-and-space pattern. The position measurement pattern P31b and the position measurement pattern P31a have different pattern densities.

One line portion 72a of the density adjustment pattern P32a is arranged between two line portions 71a of the position measurement pattern P31a. In addition, one line portion 72b of the density adjustment pattern P32b is arranged between two line portions 71b of the position measurement pattern P31b.

Line-and-space pattern P33 is obtained by combining the position measurement pattern P31a and the density adjustment pattern P32a. The line-and-space pattern P33 with the same pattern density is obtained by combining the density adjustment pattern P32b and the position measurement pattern P31b.

The beam irradiation position affected by the pattern density of the position measurement pattern P31a, and the beam irradiation position affected by the pattern density of the position measurement pattern P31b can be measured simultaneously by measuring the edge position of the line portion of the line-and-space pattern P33.

In the above embodiment, an example has been described in which the position measurement patterns and the density adjustment patterns are written twice separately (in two passes), but may be written three or more times separately. A pattern with the same shape (the same pattern density) should be ultimately formed by combining a plurality of writing patterns.

Multiple patterns with different densities are prepared, and a plurality of evaluation patterns with the same pattern density are formed by appropriately combining these patterns. By changing the measurement locations of the evaluation patterns, the edge positions of line portions affected by various pattern densities can be measured.

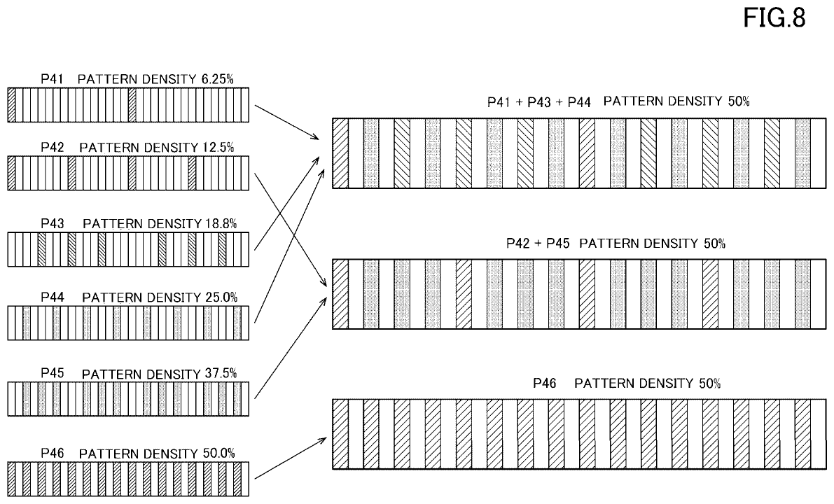

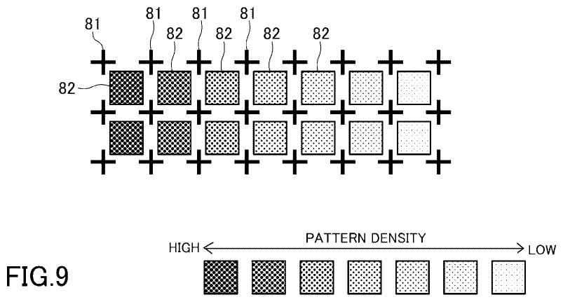

For example, six types of patterns P41 to P46 with different densities as illustrated in FIG. 8 are prepared. The patterns P41, P43 and P44 are sequentially written, and combined, thus an evaluation pattern with 50% pattern density is obtained. In addition, the patterns P42 and P43 are sequentially written, and combined, thus an evaluation pattern with 50% pattern density is obtained. The pattern P46 solely serves as an evaluation pattern with 50% pattern density.

The edge position of each line portion affected by six different types of densities can be measured by the evaluation patterns as illustrated in FIG. 8.

In the above embodiment, a writing apparatus using a multi-beam has been described; however, the present embodiment can also be applied to a writing apparatus using a single beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An evaluation pattern formation method comprising:
a step of irradiating a charged particle beam onto a sample to write a plurality of first patterns having different pattern densities; and
a step of writing a plurality of second patterns having different pattern densities so that, when combined with at least some of the plurality of first patterns, each pattern achieves the same pattern density, thereby forming a plurality of evaluation patterns with the same pattern density.

2. The evaluation pattern formation method according to claim 1, further comprising
a step of writing the plurality of first patterns together with a plurality of position measurement patterns for position measurement,
wherein each of the plurality of position measurement patterns is arranged between corresponding first patterns of the plurality of first patterns.

3. The evaluation pattern formation method according to claim 1,
wherein the plurality of first patterns are each a grid-like pattern, and
the plurality of second patterns are each a grid-like pattern surrounding a corresponding first pattern.

4. The evaluation pattern formation method according to claim 1,
wherein the plurality of first patterns and the plurality of second patterns are each line patterns, and
one of the plurality of first patterns is provided between corresponding second patterns of the plurality of second patterns.

5. The evaluation pattern formation method according to claim 1,
wherein the plurality of first patterns or the plurality of second patterns are written separately for each of the different pattern densities.

6. A position variation evaluation method,
wherein a pattern density-dependent position variation is measured using the evaluation patterns according to claim 1.
